(19) United States
(12) Patent Application Publication
(10) Pub. No.: US 2023/0318742 A1
(43) Pub. Date: Oct. 5, 2023

(54) SELECTION CIRCUIT, TRANSCEIVER DEVICE, AND SELECTION METHOD

(71) Applicant: LAPIS Technology Co., Ltd., Yokohama (JP)

(72) Inventor: Atsushi YAMAZAKI, Yokohama (JP)

(73) Assignee: LAPIS Technology Co., Ltd., Yokohama (JP)

(21) Appl. No.: 18/190,123

(22) Filed: Mar. 27, 2023

(30) Foreign Application Priority Data
Mar. 31, 2022 (JP) 2022-059688

(51) Int. Cl. H04L 1/00; H03M 13/09

(52) U.S. Cl. CPC H04L 1/0061; H03M 13/09; H04L 1/0057

(57) ABSTRACT

A selection circuit, a transceiver device, and a selection method that can enhance communication efficiency even when reliability of transmission and reception of a packet is secured are provided. The selection circuit includes: an acquisition part configured to acquire a packet to be transmitted in packet communication in which data is divided into packets and transmitted; a selection part configured to select a data length of a CRC code to be added to the packet based on a data length of the packet; and a transmitter part configured to transmit the packet to which the CRC code based on the selected data length is added.

### CROSS-REFERENCE TO RELATED APPLICATION

This application claims priority under 35 USC 119 from Japanese Patent Application No. 2022-059688 filed on Mar. 31, 2022, the disclosure of which is incorporated by reference herein.

### BACKGROUND

### Technical Field

The disclosure relates to a selection circuit, a transceiver device, and a selection method.

### Description of Related Art

Technology of transmitting a packet with an error detection code for detecting an error added thereto when transmitting the packet and determining whether a received packet has an error or damage is known in transmitting and receiving packets between devices. For example, the error detection code is a cyclic redundancy check (CRC) code which is derived using a CRC method. Detection of an error using the CRC method is, for example, a method of detecting an error of a packet by combining a CRC code derived by a transmitter-side device and a CRC code derived by a receiver-side device using transmitted and received packets. Regarding a CRC code, there is an increasing likelihood of detection of an error and damage of a received packet as the length of the CRC code becomes longer.

For example, technology of extracting a packet to be subjected to a CRC operation from an input signal frame, shifting a final bit of the packet to be located at the least significant bit, adding 0 to the most significant bit of the packet, and deriving a CRC code is disclosed in Patent Document 1 (Japanese Patent Laid-Open No. 2016-201770).

In transmitting and receiving packets, a method of securing reliability of transmission and reception of a packet by causing a receiver-side device to transmit a positive acknowledgement (ACK) or a negative acknowledgement (NACK) indicating a result of reception of a packet after having received the packet is known. Similarly, a CRC code is derived from such a signal, the CRC code is added to the signal, and the signal is transmitted.

However, when a signal to which a CRC code having the same length as a received packet is added is transmitted in transmitting a signal indicating a result of reception, the CRC code may be redundant and communication efficiency in transmitting the result of reception may decrease. On the other hand, when transmission and reception of packets are performed using a short CRC code along with a signal indicating a result of reception, a likelihood of an error and damage being detected when transmitting a packet may decrease and reliability of transmission and reception of a packet may decrease. That is, when reliability of transmission and reception of a packet is secured, there is a likelihood of communication efficiency decreasing.

The disclosure provides a selection circuit, a transceiver device, and a selection method that can enhance communication efficiency even when reliability of transmission and reception of a packet is secured.

### SUMMARY

A selection circuit according to an embodiment includes: an acquisition part configured to acquire a packet to be transmitted in packet communication in which data is divided into packets and transmitted; a selection part configured to select a data length of a CRC code to be added to the packet based on a data length of the packet; and a transmitter part configured to transmit the packet to which the CRC code based on the selected data length is added.

A transceiver device according to another embodiment includes: the selection circuit; and a receiver circuit configured to receive the packet from an external device.

A selection method according to another embodiment includes: acquiring a packet to be transmitted in packet communication in which data is divided into packets and transmitted; selecting a data length of a CRC code to be added to the packet based on a data length of the packet; and transmitting the packet to which the CRC code based on the selected data length is added.

### BRIEF DESCRIPTION OF THE DRAWINGS

FIG. 1 is a block diagram illustrating an example of a configuration of a communication system according to a first embodiment.

FIG. 2 is a block diagram illustrating an example of a configuration of a transmitter device according to the first embodiment.

FIG. 3 is a block diagram illustrating an example of a configuration of a selection communication circuit according to the first embodiment.

FIG. 4 is a diagram schematically illustrating an example of a configuration of a packet according to the first embodiment.

FIG. 5 is a diagram illustrating an example of a control flag in a command according to the first embodiment.

FIG. 6 is a flowchart illustrating an example of a flow of a method of selecting a CRC code according to the first embodiment.

FIG. 7 is a block diagram illustrating an example of a configuration of a receiver device according to a second embodiment.

FIG. 8 is a block diagram illustrating an example of a configuration of an error permitting communication circuit according to the second embodiment.

FIG. 9 is a diagram schematically illustrating an example of packet comparison according to the second embodiment.

FIG. 10 is a flowchart illustrating an example of a flow of a method of detecting a bit error according to the second embodiment.

FIG. 11 is a block diagram illustrating an example of a configuration of a transceiver device according to a third embodiment.

FIG. 12 is a block diagram illustrating an example of a configuration of a communication system according to the third embodiment.

### DESCRIPTION OF THE EMBODIMENTS

### First Embodiment

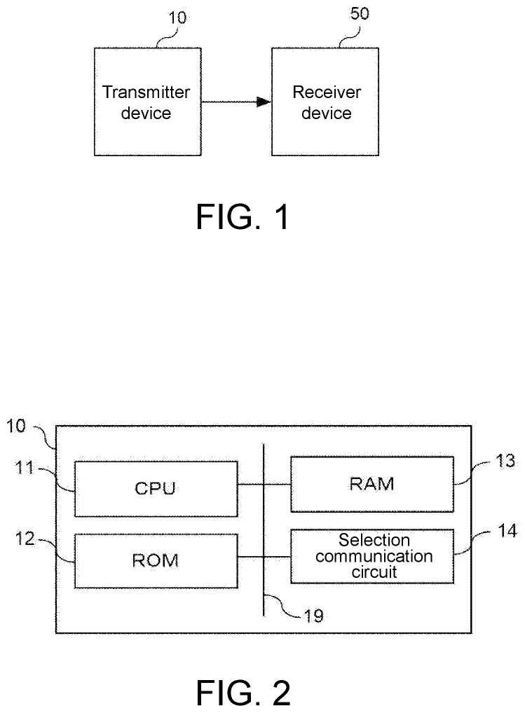

Hereinafter, an embodiment of the disclosure will be described in detail with reference to the accompanying drawings. FIG. 1 is a block diagram illustrating an example of a configuration of a communication system 1 according to a first embodiment.

For example, as illustrated in FIG. 1, the communication system 1 includes a transmitter device 10 that transmits a packet in packet communication in which data is divided into packets and a receiver device 50 that receives the packet transmitted from the transmitter device 10.

The transmitter device 10 transmits a packet in which an error detection code is added to a packet to be transmitted to the receiver device 50. Here, the error detection code in this embodiment is a cyclic redundancy check (CRC) code which is derived using a CRC method. The transmitter device 10 selects a CRC code of 8 bits (hereinafter referred to as a “8-bit CRC code”) or a CRC code of 16 bits (hereinafter referred to as a “16-bit CRC code”) based on a data length of a packet, adds the selected CRC code to the packet, and transmits the packet.

In this embodiment, it is assumed that the CRC codes to be added include an 8-bit CRC code and a 16-bit CRC code. However, the disclosure is not limited thereto. A CRC code of 32 bits, 64 bits, or 128 bits may be used, or any CRC code may be used. In this embodiment, it is assumed that a CRC code is selected from a combination of an 8-bit CRC code and a 16-bit CRC code. However, the disclosure is not limited thereto. The CRC code may be selected from a combination of an 8-bit CRC code and a 32-bit CRC code, may be selected from a combination of a 16-bit CRC code and a 32-bit CRC code, and may be any combination of CRC codes as long as they can be applied to a packet to be transmitted.

The receiver device 50 receives a packet from the transmitter device 10 and inspects whether the received packet includes an error and damage using the CRC code included in the received packet.

A configuration of the transmitter device 10 will be described below with reference to FIG. 2. FIG. 2 is a block diagram illustrating an example of the configuration of the transmitter device 10 according to this embodiment.

As illustrated in FIG. 2, the transmitter device 10 according to this embodiment includes a central processing unit (CPU) 11, a read only memory (ROM) 12, a random access memory (RAM) 13, and a selection communication circuit 14. The CPU 11, the ROM 12, the RAM 13, and the selection communication circuit 14 are connected to each other via a bus 19. Here, the selection communication circuit 14 is an example of a “selection circuit.”

The CPU 11 comprehensively controls the transmitter device 10 as a whole. The ROM 12 stores data and the like. The RAM 13 is a memory that is used as a work area at the time of performing a process.

The selection communication circuit 14 selects the 8-bit CRC code or the 16-bit CRC code depending on the packet, adds the selected CRC code to the packet, and transmits the packet.

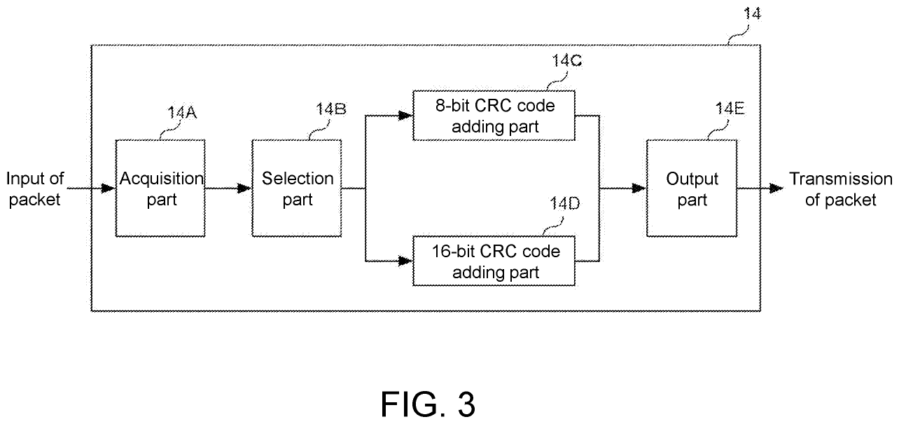

A configuration of the selection communication circuit 14 will be described below with reference to FIG. 3. FIG. 3 is a block diagram illustrating an example of the configuration of the selection communication circuit 14 according to this embodiment.

For example, as illustrated in FIG. 3, the selection communication circuit 14 includes an acquisition part 14A, a selection part 14B, an 8-bit CRC code adding part 14C, a 16-bit CRC code adding part 14D, and an output part 14E.

The acquisition part 14A acquires a packet input to the selection communication circuit 14.

The selection part 14B selects a CRC code to be added depending on the acquired packet. Specifically, the selection part 14B selects the 8-bit CRC code adding part 14C which will be described later or the 16-bit CRC code adding part 14D which will be described later based on a data length of the acquired packet and selects a CRC code to be added.

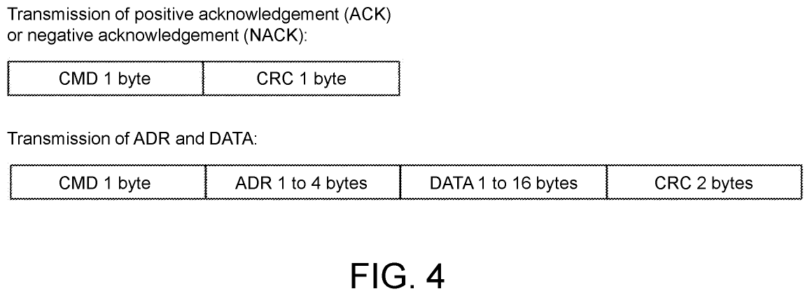

For example, as illustrated in FIG. 4, a packet in this embodiment includes CMD (command) indicating a control flag for controlling communication, ADR indicating an address, DATA indicating data, and CRC indicating a CRC code. When a packet indicating a reception result such as a positive acknowledgement or a negative acknowledgement is transmitted, the transmitter device 10 transmits a packet including CMD of 1 byte and CRC of 1 byte. For example, when a packet including ADR and DATA is transmitted, the transmitter device 10 transmits a packet including CMD of 1 byte, ADR of 1 byte to 4 bytes, DATA of 1 byte to 16 bytes, and CRC of 2 bytes.

The selection part 14B inputs the packet to the 8-bit CRC code adding part 14C which will be described later when the acquired packet includes only CMD, and inputs the packet to the 16-bit CRC code adding part 14D which will be described later when the acquired packet includes ADR and DATA.

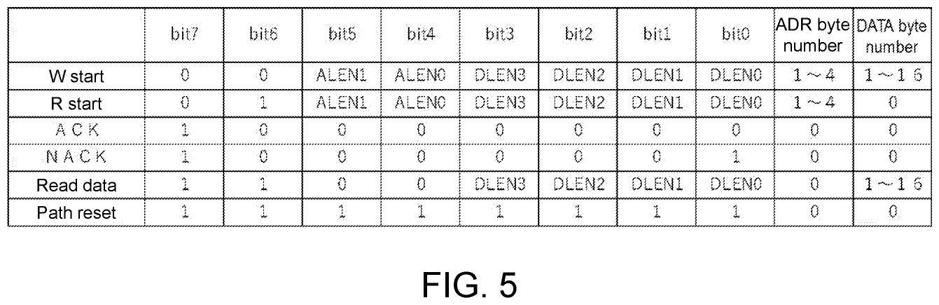

The selection part 14B according to this embodiment selects the 8-bit CRC code adding part 14C or the 16-bit CRC code adding part 14D based on data included in a packet. However, the disclosure is not limited thereto. The selection part 14B may select the 8-bit CRC code adding part 14C or the 16-bit CRC code adding part 14D based on the control flag included in CMD. For example, as illustrated in FIG. 5, CMD includes a control flag of 8 bits from bit0 to bit7, and a positive acknowledgement (ACK) and a negative acknowledgement (NACK) can be identified with reference to bit0 and bit7. Since bit0 to bit3 indicate a data length of DATA and bit4 to bit5 indicates a data length of ADR, the data lengths of DATA and ADR can be determined with reference to bit0 to bit5.

For example, when “1” is set in only bit7 or when “1” is set in only bit0 and bit7, the selection part 14B may determine a packet indicating a positive acknowledgement or a negative acknowledgement and select the 8-bit CRC code adding part 14C. The selection part 14B may determine the data length of DATA using the control flag of CMD, and determine that the packet includes ADR and DATA and select the 16-bit CRC code adding part 14D when the data length is equal to or greater than 1 byte.

The 8-bit CRC code adding part 14C derives a CRC code of 8 bits using the acquired packet and adds the derived CRC code to the acquired packet. When the acquired packet includes only CMD, the 8-bit CRC code adding part 14C performs a CRC operation on the CMD, derives a CRC code of 8 bits (1 byte), and adds the derived 8-bit CRC code to the packet.

The 16-bit CRC code adding part 14D derives a CRC code of 16 bits using the acquired packet and adds the derived CRC code to the acquired packet. When the acquired packet includes CMD, ADR, and DATA, the 16-bit CRC code adding part 14D performs a CRC operation on CMD ADR, and DATA, derives a CRC code of 16 bits (2 bytes), and adds the derived 16-bit CRC code to the packet.

The output part 14E transmits and outputs the packet to which the CRC code is added to an external device.

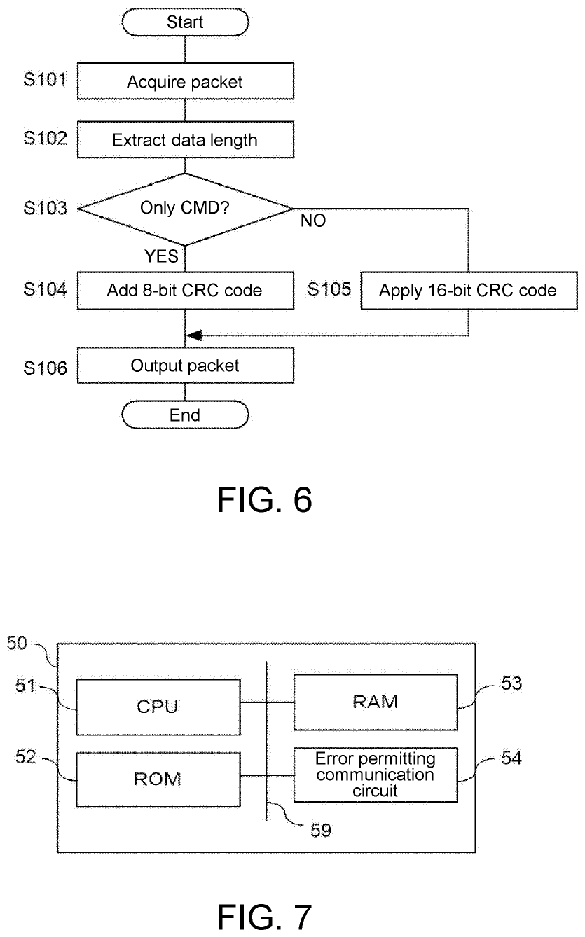

A method of selecting a CRC code according to this embodiment will be described below with reference to FIG. 6. FIG. 6 is a flowchart illustrating an example of the method of selecting a CRC code according to this embodiment.

In Step S101, the selection communication circuit 14 acquires an input packet.

In Step S102, the selection communication circuit 14 extracts a data length of the packet.

In Step S103, the selection communication circuit 14 determines whether the packet includes only CMD. When the packet includes only CMD (Step S103: YES), the selection communication circuit 14 performs Step S104. On the other hand, when the packet does not include only CMD (includes ADR and DATA) (Step S103: NO), the selection communication circuit 14 performs Step S105.

In Step S104, the selection communication circuit 14 inputs the packet to the 8-bit CRC code adding part 14C and adds an 8-bit CRC code to the packet.

In Step S105, the selection communication circuit 14 inputs the packet to the 16-bit CRC code adding part 14D and adds a 16-bit CRC code to the packet.

In Step S106, the selection communication circuit 14 transmits and outputs the packet to which the CRC code is added to an external device.

As described above, according to this embodiment, it is possible to enhance communication efficiency even when reliability of transmission and reception of a packet is secured.

In the aforementioned embodiment, the selection communication circuit 14 includes the selection part 14B configured to select a CRC code and the output part 14E configured to transmit a packet to an external device. However, the disclosure is not limited thereto. The selection part 14B configured to select a CRC code and the output part 14E configured to transmit a packet to an external device may be provided in different circuits.

In the aforementioned embodiment, an 8-bit CRC code is selected when CMD indicates a positive acknowledgement or a negative acknowledgement. However, the disclosure is not limited thereto. When CMD includes a path reset (all the control flags are “1”), an 8-bit CRC code may be selected.

### Second Embodiment

In the first embodiment, the transmitter device 10 configured to transmit a packet selects a CRC code to be added based on the packet. In this embodiment, it is assumed that the receiver device 50 receives a packet.

In the related art, when an error of 1 bit is included in a received packet, the receiver device 50 may determine that a packet cannot be transmitted and received normally and return a negative acknowledgement to request retransmission of the packet. In this embodiment, the receiver device 50 permits an error and receives a packet when a received packet includes an error of less than 1 bit.

For example, when a bit error included in a received packet is 1 bit, an acknowledgement indicated by the received packet and another acknowledgement can be distinguished in consideration of CMD and a CRC code. Specifically, when bit7 in a control flag of CMD is “1,” packets indicating a positive acknowledgement and a negative acknowledgement can be distinguished. However, when an error of 2 bits or more is included in a received packet, an acknowledgement indicated by the received packet and another acknowledgement may not be able to be distinguished.

Accordingly, in this embodiment, the receiver device 50 compares a received packet indicating a positive acknowledgement or a negative acknowledgement with a stored packet corresponding to a positive acknowledgement or a negative acknowledgement and detects whether a difference (a bit error) therebetween is 1 bit.

In the following description, a configuration of the communication system (see FIG. 1), a configuration of the transmitter device 10 (see FIG. 2), a configuration of the selection communication circuit 14 (see FIG. 3), a data configuration of a packet (see FIG. 4), an example of a control flag (see FIG. 5), and a method of selecting a CRC code (see FIG. 6) are the same as in the first embodiment, and thus description thereof will be omitted.

The configuration of the receiver device 50 will be described below with reference to FIG. 7. FIG. 7 is a block diagram illustrating an example of the configuration of the receiver device 50 according to this embodiment.

As illustrated in FIG. 7, the receiver device 50 according to this embodiment includes a CPU 51, a ROM 52, a RAM 53, and an error permitting communication circuit 54. The CPU 51, the ROM 52, the RAM 53, and the error permitting communication circuit 54 are connected to each other via a bus 59. The CPU 51, the ROM 52, and the RAM 53 are the same as the CPU 11, the ROM 12, and the RAM 13 which have been described above, and thus description thereof will be omitted. Here, the error permitting communication circuit is an example of a “receiver circuit.”

The error permitting communication circuit 54 receives a packet from an external device and determines whether an error and damage are included in the packet when the received packet includes only CMD and a CRC code.

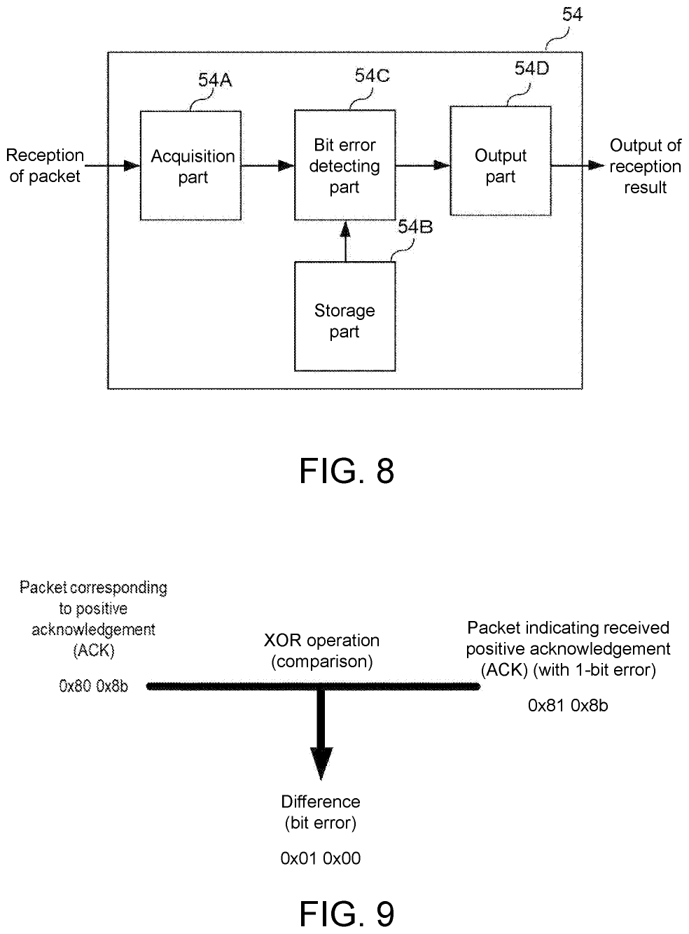

The configuration of the error permitting communication circuit 54 will be described below with reference to FIG. 8. FIG. 8 is a block diagram illustrating an example of the configuration of the error permitting communication circuit 54 according to this embodiment.

For example, as illustrated in FIG. 8, the error permitting communication circuit 54 includes an acquisition part 54A, a storage part 54B, a bit error detecting part 54C, and an output part 54D.

The acquisition part 54A acquires a packet received from an external device.

The storage part 54B stores a packet corresponding to a positive acknowledgement (hereinafter referred to as a “positive acknowledgement packet”) and a packet corresponding to a negative acknowledgement (hereinafter referred to as a “negative acknowledgement packet”). The positive acknowledgement packet is a packet including CMD indicating a positive acknowledgement and a CRC code corresponding to a positive acknowledgement, and the negative acknowledgement packet is a packet including CMD indicating a negative acknowledgement and a CRC code corresponding to a negative acknowledgement. Here, the positive acknowledgement packet and the negative acknowledgement packet are examples of an “inspection packet.”

The bit error detecting part 54C compares a received packet with the positive acknowledgement packet and the negative acknowledgement packet stored in the storage part 54B for every bit using an exclusive OR (XOR) operation and detects a difference therebetween (a bit error).

For example, as illustrated in FIG. 9, the bit error detecting part 54C can detect a difference (a bit error) by comparing CMD indicating a positive acknowledgement (ACK) and a CRC code corresponding to the positive acknowledgement which are included in the received packet with CMD indicating a positive acknowledgement and a CRC code corresponding to the positive acknowledgement which are stored therein through the XOR operation.

For example, it is assumed that the positive acknowledgement packet is “0x80 0x8b.” It is assumed that the received packet is damaged during communication to cause a bit error and the received packet indicating a positive acknowledgement is “0x81 0x8b.” The bit error detecting part 54C compares the CMD and the CRC code included in the received packet with the CMD and the CRC code corresponding to the positive acknowledgement for every bit through the XOR operation and detects “0x01 0x00” indicating a difference of 1 bit (a bit error) as the comparison result.

The bit error detecting part 54C determines that a positive acknowledgement (ACK) has been received when the difference (the bit error) is less than 1 bit. Similarly, the bit error detecting part 54C compares the received packet with the negative acknowledgement packet for every bit, detects a bit error of 1 bit, and determines that a negative acknowledgement (NACK) has been received when the difference (the bit error) is less than 1 bit.

As the method of determining whether the difference (bit error) is less than 1 bit from the comparison result, a method of searching a bit string for a bit of “1” in rightward and leftward directions and comparing positions firstly detected is used. For example, a bit string which is a result of the XOR operation is searched while shifting in the rightward direction (a lower bit direction) and the leftward direction (an upper bit direction). The positions of the bit firstly detected through search in the directions are stored, and it is detected that an error of 1 bit is included in the result of XOR operation when the detected positions are the same. On the other hand, when the positions of the bit firstly detected through search in the directions are different, it is detected that there is an error of 2 bits or more. When a bit of “1” has not been detected through search in the directions, it is detected that there is no error.

The output part 54D outputs the received packet and the error detection result to the RAM 53.

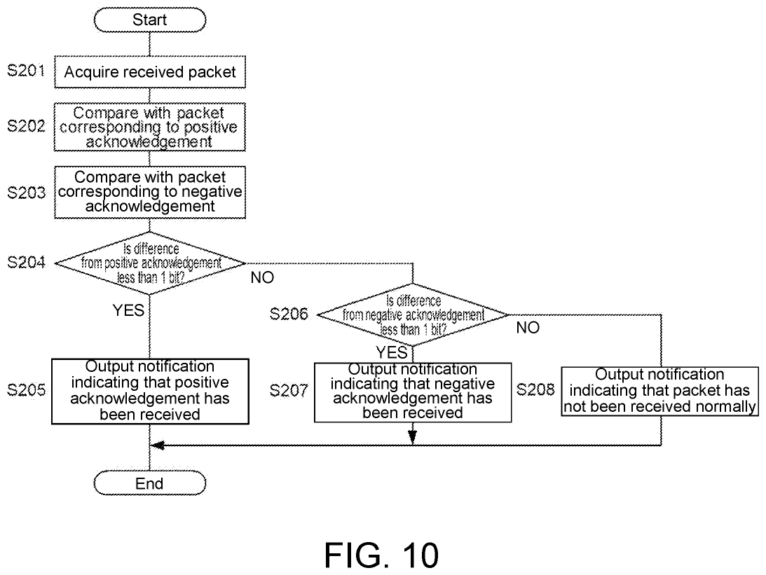

A method of permitting an error according to this embodiment will be described below with reference to FIG. 10. FIG. 10 is a flowchart illustrating an example of the method of permitting an error according to this embodiment.

In Step S201, the error permitting communication circuit 54 acquires a packet received from an external device.

In Step S202, the error permitting communication circuit 54 compares the received packet with a positive acknowledgement packet stored therein.

In Step S203, the error permitting communication circuit 54 compares the received packet with a negative acknowledgement packet stored therein.

In Step S204, the error permitting communication circuit 54 determines whether a difference (a bit error) from the positive acknowledgement is less than 1 bit as a result of comparison between the received packet and the positive acknowledgement packet. When the difference (bit error) from the positive acknowledgement is less than 1 bit (Step S204: YES), the error permitting communication circuit 54 performs Step S205. On the other hand, when the difference (bit error) from the positive acknowledgement is not less than 1 bit (the difference (bit error) from the positive acknowledgement packet is greater than 1) (Step S204: NO), the error permitting communication circuit 54 performs Step S206.

In Step S205, the error permitting communication circuit 54 outputs the received packet and a notification indicating that a positive acknowledgement has been received as an error detection result.

In Step S206, the error permitting communication circuit 54 determines whether a difference (bit error) between the received packet and the negative acknowledgement packet is less than 1 bit. When the difference (bit error) from the negative acknowledgement packet is less than 1 bit (Step S206: YES), the error permitting communication circuit 54 performs Step S207. On the other hand, when the difference (bit error) from the negative acknowledgement is not less than 1 bit (the difference (bit error) from the negative acknowledgement packet is greater than 1) (Step S206: NO), the error permitting communication circuit 54 performs Step S208.

In Step S207, the error permitting communication circuit 54 outputs the received packet and a notification indicating that a negative acknowledgement has been received as the error detection result.

In Step S208, the error permitting communication circuit 54 outputs a notification indicating that a packet has not been received normally as the error detection result.

As described above, even when a received packet includes an error and damage, it is possible to receive the packet by permitting the error and damage and to reduce the number of times of retransmission of the packet. That is, according to this embodiment, it is possible to enhance communication efficiency while securing reliability of transmission and reception of a packet.

In this embodiment, an error of a packet indicating a positive acknowledgement and a negative acknowledgement is permitted. However, the disclosure is not limited thereto. An error of a packet indicating path reset may be permitted.

In this embodiment, a bit error is detected by searching a result of the XOR operation for a bit in the rightward and leftward directions. However, the disclosure is not limited thereto. The bit error may be detected using a mask bit. For example, a bit error may be detected by comparing a result of the XOR operation with a plurality of mask bits in which only 1 bit is set to “1” and searching for a corresponding mask.

In this embodiment, a received packet, a positive acknowledgement packet, and a negative acknowledgement packet are 2 bytes. However, the disclosure is not limited thereto. The received packet, the positive acknowledgement packet, and the negative acknowledgement packet may be 3 bytes or more.

In this embodiment, the received packet, the positive acknowledgement packet, and the negative acknowledgement are compared through the XOR operation. However, the disclosure is not limited thereto. For example, packets including inverted bits of the received packet, the positive acknowledgement packet, and the negative acknowledgement packet may be compared through the XOR operation. In this case, “0” in the comparison result is a bit error.

### Third Embodiment

In the first embodiment, the transmitter device 10 including the selection communication circuit 14 transmits a packet. In the second embodiment, the receiver device 50 including the error permitting communication circuit 54 receives a packet. In this embodiment, a transceiver device including the selection communication circuit 14 and the error permitting communication circuit 54 transmits and receives a packet.

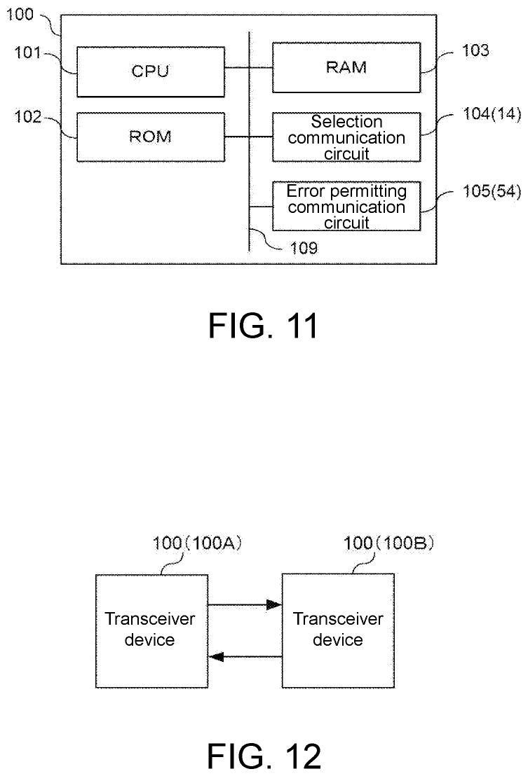

A configuration of a transceiver device 100 will be described below with reference to FIG. 11. FIG. 11 is a block diagram illustrating an example of the configuration of the transceiver device 100 according to this embodiment.

As illustrated in FIG. 11, the transceiver device 100 according to this embodiment includes a CPU 101, a ROM 102, a RAM 103, a selection communication circuit 104, and an error permitting communication circuit 105. The CPU 101, the ROM 102, the RAM 103, the selection communication circuit 104, and the error permitting communication circuit 105 are connected to each other via a bus 109. The CPU 101, the ROM 102, the RAM 103, the selection communication circuit 104, and the error permitting communication circuit 105 are the same as the CPU 11, the ROM 12, the RAM 13, the selection communication circuit 14, and the error permitting communication circuit 54, and thus description thereof will be omitted. That is, the transceiver device 100 includes the selection communication circuit 104 and the error permitting communication circuit 105.

For example, as illustrated in FIG. 12, a transceiver device 100A communicates with another transceiver device 100B. For example, the transceiver device 100A adds a CRC code to a packet and transmits the packet using the selection communication circuit 104 when the packet is transmitted, and detects a bit error of a packet using the error permitting communication circuit 105 and receives the packet when the packet is received.

As described above, according to the embodiments, it is possible to further enhance communication efficiency even when reliability of transmission and reception of a packet is secured.

The configurations of the receiver device, the transmitter device, and the transceiver device described above in the embodiments are examples, and the configurations may be modified without departing from the gist of the embodiments.

What is claimed is:

1. A selection circuit comprising:
an acquisition part configured to acquire a packet to be transmitted in packet communication in which data is divided into packets and transmitted;
a selection part configured to select a data length of a CRC code to be added to the packet based on a data length of the packet; and
a transmitter part configured to transmit the packet to which the CRC code based on the selected data length is added.

2. The selection circuit according to claim 1, wherein the packet includes a control flag for controlling the packet communication, and
wherein the selection part determines the data length of the packet using the control flag.

3. The selection circuit according to claim 2, wherein the selection part selects a CRC code of 8 bits in response to the control flag indicating a positive acknowledgement, a negative acknowledgement, or a path reset.

4. The selection circuit according to claim 2, wherein the selection part selects a CRC code of 16 bits in response to the packet including data other than the control flag.

5. The selection circuit according to claim 3, wherein the selection part selects a CRC code of 16 bits in response to the packet including data other than the control flag.

6. A transceiver device comprising:
the selection circuit according to claim 1; and
a receiver circuit configured to receive the packet from an external device.

7. The transceiver device according to claim 6, wherein the packet includes a control flag for controlling the packet communication and the CRC code, and
wherein the receiver circuit performs:
storing an inspection packet including at least one of a packet including a control flag indicating a positive acknowledgement and a CRC code corresponding to a positive acknowledgement and a packet including a control flag indicating a negative acknowledgement and a CRC code corresponding to a negative acknowledgement in advance,
receiving the packet from the external device, and
detecting a bit error of the received packet by comparing the received packet with the inspection packet.

8. The transceiver device according to claim 7, wherein the receiver circuit permits an error bit in the received packet to 1 bit.

9. The transceiver device according to claim 7, wherein the receiver circuit compares the received packet with the inspection packet using an exclusive OR.

10. The transceiver device according to claim 8, wherein the receiver circuit compares the received packet with the inspection packet using an exclusive OR.

11. The transceiver device according to claim 9, wherein the receiver circuit detects whether the bit error is less than 1 bit by bit-shifting an operation result of the exclusive OR of the received packet and the inspection packet in an upper bit direction and a lower bit direction.

12. The transceiver device according to claim 10, wherein the receiver circuit detects whether the bit error is less than 1 bit by bit-shifting an operation result of the exclusive OR of the received packet and the inspection packet in an upper bit direction and a lower bit direction.

13. A selection method comprising:
acquiring a packet to be transmitted in packet communication in which data is divided into packets and transmitted;
selecting a data length of a CRC code to be added to the packet based on a data length of the packet; and
transmitting the packet to which the CRC code based on the selected data length is added.
